(19) United States
(12) Patent Application Publication
(10) Pub. No.: US 2024/0271320 A1
(43) Pub. Date: Aug. 15, 2024

(54) SEED SUBSTRATE FOR NITRIDE CRYSTAL GROWTH, PRODUCTION METHOD FOR NITRIDE CRYSTAL SUBSTRATE, AND PEELED INTERMEDIATE

(71) Applicant: SUMITOMO CHEMICAL COMPANY, LIMITED, Tokyo (JP)

(72) Inventors: Masafumi YOKOYAMA, Hitachi-shi (JP); Hajime FUJIKURA, Hitachi-shi (JP); Taichiro KONNO, Hitachi-shi (JP)

(73) Assignee: SUMITOMO CHEMICAL COMPANY, LIMITED, Tokyo (JP)

(21) Appl. No.: 18/434,507

(22) Filed: Feb. 6, 2024

(30) Foreign Application Priority Data
Feb. 8, 2023 (JP) 2023-017784

(51) Int. Cl. C30B 25/20; C30B 25/18; C30B 29/38

(52) U.S. Cl. CPC C30B 25/20; C30B 29/38; C30B 25/183

(57) ABSTRACT

To easily obtain a nitride crystal substrate. A seed substrate for nitride crystal growth includes: a base substrate; an intermediate layer provided above the base substrate and including n-type group III nitride crystal; and a cover layer provided on the intermediate layer and including group II nitride crystal having a carrier concentration lower than that of the intermediate layer, wherein the intermediate layer is porous, a surface of the cover layer has an arithmetic mean roughness of 1.0 nm or less, and the surface of the cover layer has a root mean square roughness of 2.0 nm or less, the arithmetic mean roughness and the root mean square roughness being values obtained when the surface of the cover layer is observed with an atomic force microscope in a field of view of 5 μm square.

### FIELD AND BACKGROUND OF THE INVENTION

The present disclosure relates to a seed substrate for nitride crystal growth, a production method for a nitride crystal substrate, and a peeled intermediate.

Various production methods for obtaining nitride crystal substrates comprising group III nitride crystal have been disclosed (see, for example, Japanese Patent Laid Open Publication No. 2003-178984).

### SUMMARY OF THE INVENTION

The present disclosure has an object to stably grow a regrowth layer and to easily peel the regrowth layer.

According to an aspect of the present disclosure, there is provided a seed substrate for nitride crystal growth, comprising:
a base substrate;
an intermediate layer provided above the base substrate and including n-type group III nitride crystal; and
a cover layer provided on the intermediate layer and including group III nitride crystal having a carrier concentration lower than that of the intermediate layer, wherein
the intermediate layer is porous,
a surface of the cover layer has an arithmetic mean roughness of 1.0 nm or less, and
the surface of the cover layer has a root mean square roughness of 2.0 nm or less,
the arithmetic mean roughness and the root mean square roughness being values obtained when the surface of the cover layer is observed with an atomic force microscope in a field of view of 5 μm square.

According to another aspect of the present disclosure, there is provided a production method for a nitride crystal substrate, the method comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than that of the intermediate layer;
(d) making the intermediate layer porous through dislocations in the cover layer by performing an electrochemical process while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary.

According to another aspect of the present disclosure, there is provided a peeled intermediate obtained by the above production method for a nitride crystal substrate, the peeled intermediate comprising:
at least the cover layer and the regrowth layer.

According to the present disclosure, the regrowth layer can be grown stably and peeled off easily.

### BRIEF DESCRIPTION OF THE DRAWINGS

FIG. 1 is a schematic cross-sectional view illustrating a seed substrate for nitride crystal growth according to one embodiment of the present disclosure.

FIG. 2 is a flowchart illustrating a production method for a nitride crystal substrate according to the embodiment of the present disclosure.

FIG. 3A is a schematic cross-sectional view illustrating the production method for a nitride crystal substrate according to the embodiment of the present disclosure.

FIG. 3B is a schematic cross-sectional view illustrating the production method for a nitride crystal substrate according to the embodiment of the present disclosure.

FIG. 3C is a schematic cross-sectional view illustrating the production method for a nitride crystal substrate according to the embodiment of the present disclosure.

FIG. 4 is a schematic cross-sectional view illustrating the production method for a nitride crystal substrate according to the embodiment of the present disclosure.

FIG. 5 is a schematic cross-sectional view illustrating the production method for a nitride crystal substrate according to the embodiment of the present disclosure.

FIG. 6 is a schematic cross-sectional view illustrating the production method for a nitride crystal substrate according to the embodiment of the present disclosure.

FIG. 7 is a schematic cross-sectional view illustrating the production method for a nitride crystal substrate according to the embodiment of the present disclosure.

FIG. 8A is a diagram obtained by observing a surface of Sample A1 with an atomic force microscopy.

FIG. 8B is a diagram obtained by observing a surface of Sample A2 with the atomic force microscopy.

FIG. 8C is a diagram obtained by observing a surface of Sample A3 with the atomic force microscopy.

FIG. 9 is a diagram obtained by observing a cross section of Sample A1 with a scanning electron microscopy.

FIG. 10 is a diagram obtained by observing a cross section of Sample A2 at high magnification with the scanning electron microscopy.

FIG. 11 is a diagram showing a cross section of Sample A1, from which a regrowth layer has been peeled off, as observed with the scanning electron microscopy.

### DETAILED DESCRIPTION

### Findings Obtained by Inventors

As a production method for obtaining a nitride crystal substrate, for example, a Void-Assisted Separation (VAS) method is known as described in the above-mentioned Patent Document 1.

In the VAS method, a GaN layer and a Ti layer are first grown on a sapphire substrate in this order. Next, voids are formed in the GaN layer while the Ti layer is modified into the meshed TiN layer by heat treatment in an atmosphere containing hydrogen (H₂) gas and ammonia (NH₃) gas. A GaN regrowth layer is grown on the TiN and GaN layers in this state. The GaN regrowth layer is then peeled from the substrate by using, as a border, the GaN layer with the voids. As a result, a GaN crystal substrate can be obtained from the peeled GaN regrowth layer.

However, in the VAS method, it is difficult to form a TiN layer with a uniform mesh in the plane and a GaN layer with uniform voids in the plane. This also makes it difficult to obtain a GaN crystal substrate with a large area.

Therefore, the inventors have considered an electrochemical process as a method of forming voids in a nitride layer. As a result of the studies diligently conducted by the inventors, they have succeeded in stably growing a regrowth layer and easily peeling off the regrowth layer by a method described below.

The present disclosure below is based on the above findings obtained by the inventors.

### One Embodiment of Present Disclosure

One embodiment of the present disclosure will be described below with reference to the drawings.

### (1) Seed Substrate for Nitride Crystal Growth

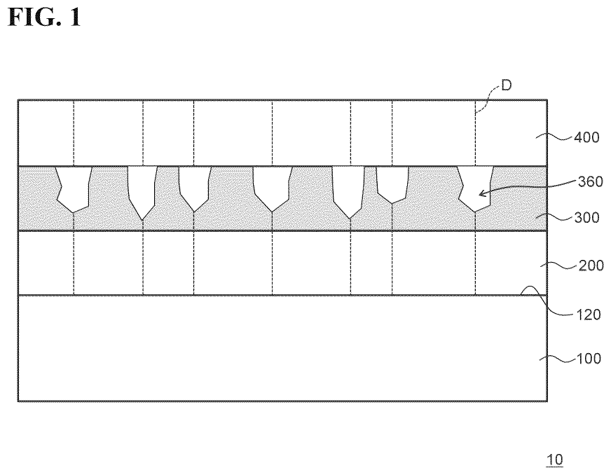

A seed substrate for nitride crystal growth according to a present embodiment will be described with reference to FIG. 1. In FIG. 1, hatching of cross sections excluding an intermediate layer 300 is omitted.

In the following, in group III nitride crystal with a wurtzite structure, a <0001> axis (e.g., axis) is referred to as a “c-axis”, and (0001) as a “c-plane”. The (0001) is sometimes referred to as a “+c-plane (group III element polar plane)”, and (000-1) as a “-c-plane (nitrogen (N) polar plane)”. The term “carrier concentration” in the present disclosure means a free carrier concentration at room temperature (22° C.).

As illustrated in FIG. 1, a seed substrate 10 for nitride crystal growth according to the present embodiment is configured, for example, as an intermediate having a laminated structure for stably growing a regrowth layer 500 described later and then peeling off the regrowth layer 500.

Specifically, the seed substrate 10 for nitride crystal growth of the present embodiment has, for example, a base substrate 100, a base layer 200, an intermediate layer 300, and a cover layer 400.

### Base Substrate

In the present embodiment, the base substrate 100 is, for example, a substrate comprising a material different from a group III nitride. Specifically, examples of the base substrate 100 include a sapphire substrate, a silicon carbide (SiC) substrate, a silicon (Si) substrate, and a gallium arsenide (GaAs) substrate. The base substrate 100 may be insulating or conductive. Here, the base substrate 100 is, for example, a sapphire substrate.

Alternatively, the base substrate 100 may be a free-standing substrate comprising a group III nitride (e.g., a GaN free-standing substrate).

The diameter of the base substrate 100 is, for example, 2 inches (50.8 mm) or more, or may be 4 inches (100 mm) or more. This allows for the growth of the regrowth layer 500 with a large area, described later.

The thickness of the base substrate 100 is, for example, 150 μm or more and 3 mm or less.

The base substrate 100 has a main surface 120, which becomes a growth surface, for example. In a case where the base substrate 100 is a sapphire or SiC substrate, a crystal plane with a low index closest to the main surface 120 is, for example, the c-plane (+c-plane). In a case where the base substrate 100 is a Si substrate or GaAs substrate, the crystal plane with the low index closest to the main surface 120 is, for example, (001) or (111).

In the present embodiment, the c-plane of the base substrate 100 may be inclined with respect to the main surface 120. That is, the c-axis of the base substrate 100 may be inclined at a predetermined off angle with respect to a normal of the main surface 120. The off angle of the base substrate 100 is, for example, 0° or more and 5° or less.

The main surface 120 of the base substrate 100 has an arithmetic mean roughness (Ra) of, for example, less than 0.3 nm.

### Base Layer

The base layer 200 is provided on, for example, the base substrate 100 and includes group III nitride crystal (comprises group III nitride crystal).

The base layer 200 has, as a layer including group III nitride crystal, for example, an aluminum nitride (AlN) buffer layer and a gallium nitride (GaN) layer which are laminated on the base substrate 100 in this order. However, the base layer 200 may not have an AlN buffer layer.

The GaN layer in the base layer 200 is, for example, an n-type. The GaN layer contains, for example, Si as an n-type impurity (n-type dopant).

The carrier concentration in the GaN layer of the base layer 200 is lower than, for example, the carrier concentration in the intermediate layer 300 described later. In other words, the n-type impurity concentration in the GaN layer of the base layer 200 is lower than, for example, the n-type impurity concentration in the intermediate layer 300 described later. Specifically, the carrier concentration (and n-type impurity concentration) in the base layer 200 is less than or equal to, for example, 1×10¹⁸ cm⁻³. Thus, in a porous step S50 of making the intermediate layer 300 porous by performing an electrochemical process, the base layer 200 can function as an etching stopper located on a lower side of the intermediate layer 300.

The lower limit of the carrier concentration in the GaN layer of the base layer 200 is not limited. However, the carrier concentration in the GaN layer of the base layer 200 may be, for example, 1×10¹⁶ cm⁻³ or more. Thus, since the base layer 200 itself has some conductivity, in the porous step S50 described later, etching of the intermediate layer 300 can progress toward a lower portion of the intermediate layer 300 through the electrochemical process.

The thickness of the base layer 200 is not particularly limited. However, the thickness of the base layer 200 may be, for example, more than 0 nm and 5 μm or less. By setting the thickness of the base layer 200 to 5 μm or less, the total thickness of the stacked layers on the base substrate 100 can be adjusted to 15 μm or less, for example. This can suppress cracking that would be caused by a difference in linear expansion coefficient between respective layers, including the base substrate 100 and the base layer 200.

The crystal plane with the low index closest to the surface of the base layer 200 is the c-plane of the GaN layer.

### Intermediate Layer

The intermediate layer 300 is provided, for example, on the base layer 200 located above the base substrate 100 and includes n-type group III nitride crystal (a portion of the intermediate layer 300 other than voids 360 described later comprises group III nitride crystal).

The intermediate layer 300 comprises, for example, a Si-doped GaN layer, as a layer including n-type group III nitride crystal.

In the present embodiment, the carrier concentration in the intermediate layer 300 is higher than, for example, each of the carrier concentration in the base layer 200 and the carrier concentration of the cover layer 400 described later. In other words, the n-type impurity concentration in the intermediate layer 300 is higher than, for example, each of the n-type impurity concentration in the base layer 200 and the n-type impurity concentration in the cover layer 400 described later. Specifically, the carrier concentration (and n-type impurity concentration) in the intermediate layer 300 is, for example, 1×10¹⁸ cm⁻³ or more, or may be 1×10¹⁹ cm⁻³ or more.

The upper limit of the carrier concentration in the intermediate layer 300 is not limited. However, the carrier concentration in the intermediate layer 300 may be, for example, 1×10²⁰ cm⁻³ or less, or 5×10¹⁹ cm⁻³ or less. This can suppress degradation of the crystallinity of the intermediate layer 300.

In the present embodiment, the intermediate layer 300, which has a relatively high carrier concentration, is configured to be porous while including the plurality of voids 360 by selective etching in the electrochemical process. Thus, the regrowth layer 500 regrown on the seed substrate 10 for nitride crystal growth can be peeled off from the base substrate 100 by using at least a portion of the porous intermediate layer 300 as a boundary.

In the present embodiment, the voids 360 are formed in the intermediate layer 300 by performing the electrochemical process to allow an electrolyte to penetrate the intermediate layer 300 through dislocations D passing through the cover layer 400 in its thickness direction.

Thus, each of the voids 360 in the intermediate layer 300 is formed at a position overlapping, for example, each of the dislocations D in the cover layer 400 described later. The plurality of voids 360 in the intermediate layer 300 extends, for example, from the bottom surface of the cover layer 400 toward the base substrate 100 in the thickness direction. However, the voids 360 do not need to reach the base layer 200.

Meanwhile, partition wall portions of the intermediate layer 300 other than the voids 360 connect an upper portion of the base layer 200 or a lower portion of the intermediate layer 300 with the cover layer 400. Thus, the intermediate layer 300 maintains a constant thickness even though it has the plurality of voids 360.

In the present embodiment, the thickness of the intermediate layer 300 is, for example, more than 100 nm, or may be 500 nm or more, or 1 μm or more. Thus, the large voids 360 can be formed in the intermediate layer 300.

The upper limit of the thickness of the intermediate layer 300 is not limited. However, the thickness of the intermediate layer 300 may be 10 μm or less. By setting the thickness of the intermediate layer 300 to 10 μm or less, the total thickness of the laminated layers on the base substrate 100 can be adjusted to 15 μm or less, for example. This can suppress cracking that would be caused by a difference in linear expansion coefficient between respective layers, including the base substrate 100 and the intermediate layer 300.

In the present embodiment, the length of each of the plurality of voids 360 in the intermediate layer 300 in a direction along the main surface 120 of the base substrate 100 is, for example, 30 nm or more, or may be 100 nm or more, when viewed in any cross section orthogonal to the main surface 120 of the base substrate 100. Thus, in a regrowth step S60 of regrowing the regrowth layer 500 on the seed substrate 10 for nitride crystal growth as described later, the voids 360 in the intermediate layer 300 can be maintained.

In the present embodiment, the length of each of the plurality of voids 360 in the intermediate layer 300 in the direction along the main surface 120 of the base substrate 100 is, for example, 30 nm or more, or may be 100 nm or more, when viewed in a cross section along the main surface of the base substrate 100 and at a depth of 30 nm below the bottom surface of the cover layer 400 described later. Also, with this configuration, in the regrowth step S60 of regrowing the regrowth layer 500 on the seed substrate 10 for nitride crystal growth as described later, the voids 360 in the intermediate layer 300 can be maintained.

The upper limit of the length of each of the voids 360 in the intermediate layer 300 in the direction along the main surface 120 of the base substrate 100 is not limited. However, the length of each of the voids 360 in the direction along the main surface 120 of the base substrate 100 may be 10 μm or less. Thus, by adjusting conditions for the electrochemical process appropriately in the porous step S50 of making the intermediate layer 300 porous as described later, the cover layer 400 can be prevented from being peeled off due to outgassing when etching the intermediate layer 300.

In the present embodiment, the depth of each of the plurality of voids 360 in the thickness direction of the intermediate layer 300 is, for example, more than 100 nm, or may be 500 nm or more, or 1 μm or more. Also, with this configuration, in the regrowth step S60 of regrowing the regrowth layer 500 on the seed substrate 10 for nitride crystal growth as described later, the voids 360 in the intermediate layer 300 can be maintained.

The upper limit of the depth of each of the voids 360 is not limited. However, the depth of the void 360 may be less than or equal to the thickness of the intermediate layer 300. Thus, in a peeling step S70 of peeling off the regrowth layer 500 as described later, excessive spread of the peeling from the intermediate layer 300 to other layers can be suppressed.

### Cover Layer

For example, the cover layer 400 is provided on the intermediate layer 300 and includes group III nitride crystal (a portion of the cover layer 400 other than micro voids described later comprises group III nitride crystal).

The cover layer 400 comprises, for example, a Si-doped GaN layer, as a layer including group III nitride crystal. However, the cover layer 400 may be, for example, a non-doped layer (non-doped GaN layer).

In the present embodiment, the carrier concentration in the cover layer 400 is lower than, for example, the carrier concentration in the intermediate layer 300. In other words, the n-type impurity concentration in the cover layer 400 is lower than, for example, the n-type impurity concentration in the intermediate layer 300. Specifically, the carrier concentration (and n-type impurity concentration) in the cover layer 400 is, for example, less than or equal to 1×10¹⁸ cm⁻³. Thus, in the porous step S50 of making the intermediate layer 300 porous, the intermediate layer 300 can be selectively made porous while suppressing etching of the cover layer 400. That is, under a predetermined voltage, the size of the micro voids in the cover layer 400 can be prevented from increasing, whereas the size of the voids 360 in the intermediate layer 300 increases.

The lower limit of the carrier concentration in the cover layer 400 is not limited. However, the carrier concentration in the cover layer 400 may be, for example, 1×10¹⁶ cm⁻³ or more, or 1×10¹⁷ cm⁻³ or more. In this way, since the cover layer 400 itself has conductivity, the intermediate layer 300 can be connected to an anode 842 via the cover layer 400, and the entire intermediate layer 300 can be equipotential with the anode 842 during the electrochemical process performed in the porous step S50 of making the intermediate layer 300 porous.

In the present embodiment, the cover layer 400 has the plurality of dislocations D passing therethrough in its thickness direction, for example. A dislocation density on the surface of the cover layer 400 is, for example, 1×10⁸ cm⁻² or more and 1×10⁹ cm⁻² or less. As described above, the electrochemical process can make the intermediate layer 300 porous by allowing the electrolyte to penetrate the intermediate layer 300 through the dislocations D passing through the cover layer 400 in its thickness direction.

In contrast, in the present embodiment, the surface of the cover layer 400, in which its carrier concentration is relatively low, is hardly etched. In other words, even when the cover layer 400 has the plurality of dislocations D as described above, excessive etching does not occur on the surface of the cover layer 400 near the dislocations D. Consequently, the surface condition of the cover layer 400 is maintained flat.

Specifically, the surface of the cover layer 400 has an arithmetic mean roughness (Ra) of, for example, 1.0 nm or less, and the surface of the cover layer 400 has a root mean square roughness (RMS) of, for example, 2.0 nm or less. Alternatively, the Ra of the surface of the cover layer 400 may be, for example, 0.5 nm or less, and the RMS of the surface of the cover layer 400 may be, for example, 1.0 nm or less. Here, Ra and RMS are the values obtained when the surface of the cover layer 400 is observed with the atomic force microscope (AFM) in a field of view of 5 μm square.

By maintaining a small surface roughness of the cover layer 400 as described above, a thick regrowth layer 500 with good crystallinity can be stably grown on the cover layer 400.

The lower limits of Ra and RMS of the surface of the cover layer 400 are not limited and may be close to the Ra and RMS of the main surface 120 of the base substrate 100, respectively. Specifically, the lower limits of Ra and RMS of the surface of the cover layer 400 may be 0.1 nm and 0.2 nm, respectively.

The surface of the cover layer 400 has no etching occurring near the dislocations D. However, at any position below the surface of the cover layer 400, micro voids (not illustrated) that have been etched may exist in an area including the dislocation D. In this case, the micro voids are formed starting at a position below the surface of the cover layer 400 and spread out as they approach the intermediate layer 300.

In the present embodiment, the thickness of the cover layer 400 is, for example, 10 nm or more and 2 μm or less, or may be 50 nm or more and 1.5 μm or less. By setting the thickness of the cover layer 400 to 10 nm or more or 50 nm or more, in the porous step S50 of making the intermediate layer 300 porous, the cover layer 400 can be prevented from being peeled off due to outgassing when etching the intermediate layer 300. On the other hand, by setting the thickness of the cover layer 400 to 2 μm or less or 1.5 μm or less, in the porous step S50 of making the intermediate layer 300 porous, the electrolyte is allowed to stably reach the intermediate layer 300 through the dislocations D of the cover layer 400. Thus, the formation of the voids in the intermediate layer 300 can be performed stably.

### (2) Production Method for Nitride Crystal Substrate

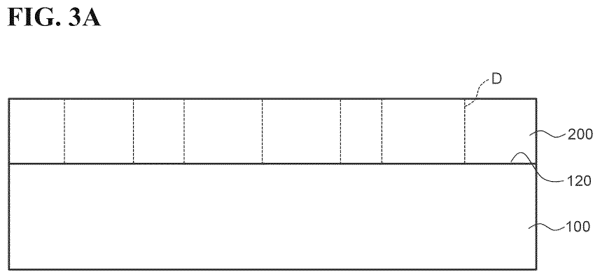

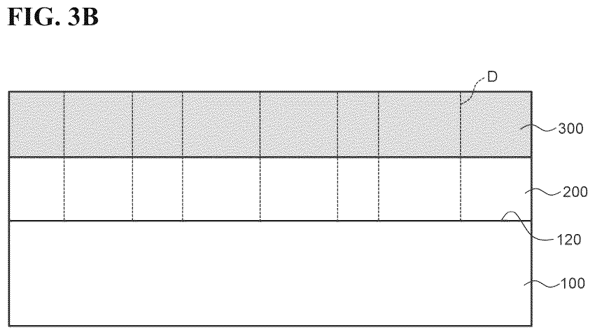

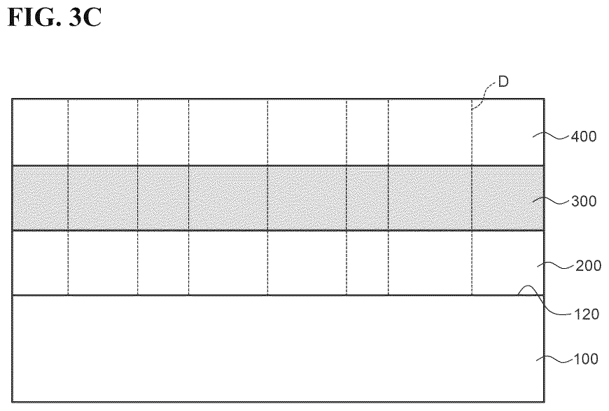

Referring to FIGS. 1 to 7, the production method for a nitride crystal substrate according to the present embodiment is described. In FIGS. 3B to 7, hatching of the cross sections, except for the intermediate layer 300, is omitted.

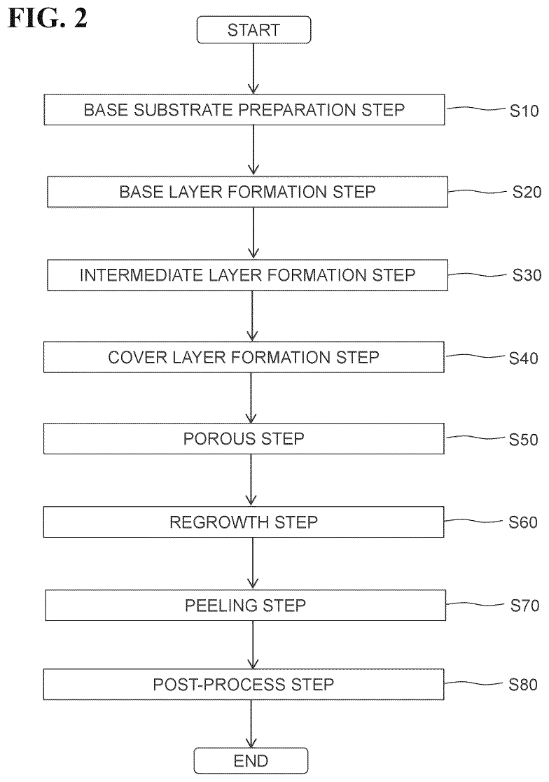

As illustrated in FIG. 2, the production method for a nitride crystal substrate according to the present embodiment includes, for example, a base substrate preparation step S10, a base layer formation step S20, an intermediate layer formation step S30, a cover layer formation step S40, a porous step S50, a regrowth step S60, a peeling step S70, and a post-process step S80.

### S10: Base Substrate Preparation Step

First, as illustrated in FIG. 3A, the base substrate 100 is prepared. Here, the base substrate 100 is, for example, a sapphire substrate. The base substrate 100 has a diameter of, for example, 2 inches (50.8 mm) or more.

The base substrate 100 has the main surface 120, which becomes the growth surface, for example. The crystal plane with a low index closest to the main surface 120 is, for example, the c-plane (+c-plane). As described above, the c-axis of the base substrate 100 may be inclined at a predetermined off angle with respect to the normal of the main surface 120.

### S20: Base Layer Formation Step

After preparing the base substrate 100, a base layer 200 including group III nitride crystal is formed (a base layer 200 comprising group III nitride crystal is formed) on the base substrate 100, for example, by a vapor phase growth method, as illustrated in FIG. 3A.

Specifically, an AlN buffer layer is grown by supplying aluminum chloride (AlCl₃) gas and NH₃ gas to the base substrate 100 heated to a predetermined growth temperature, for example, by a hydride vapor phase epitaxy (HVPE) method. Next, a GaN layer is grown by supplying gallium chloride (GaCl) gas and NH₃ gas to the base substrate 100 heated to the predetermined growth temperature. The growth temperature of each layer is, for example, 900° C. or higher and 1100° C. or lower. In the way above, the AlN buffer layer and the GaN layer are formed as the base layer 200 on the main surface 120 of the base substrate 100 in this order.

In the present embodiment, the base layer 200 is, for example, an n-type. Specifically, when growing the GaN layer as the base layer 200, dichlorosilane (SiH₂Cl₂) gas is further supplied as an n-type dopant gas to grow a Si-doped GaN layer.

In the present embodiment, a carrier concentration in the GaN layer of the base layer 200 is lower than, for example, a carrier concentration in the intermediate layer 300. In other words, an n-type impurity concentration in the GaN layer of the base layer 200 is lower than, for example, an n-type impurity concentration in the intermediate layer 300. Specifically, the carrier concentration (and n-type impurity concentration) in the base layer 200 is, for example, 1×10¹⁸ cm⁻³ or less.

In the present embodiment, the crystal plane with the low index closest to the surface of the base layer 200 is the c-plane of the GaN layer. By forming a flat surface of the base layer 200 with this crystal plane in advance, the intermediate layer 300 and cover layer 400 with good crystallinity can be grown on the surface of the base layer 200.

### S30: Intermediate Layer Formation Step

After the base layer 200 is formed, the intermediate layer 300 including n-type group III nitride crystal is formed on the base layer 200 located above the base substrate 100, for example, by the vapor phase growth method, as illustrated in FIG. 3B.

Specifically, a Si-doped GaN layer is grown as the intermediate layer 300 on the base layer 200 using, for example, a metal organic vapor phase epitaxy (MOVPE) method, by supplying trimethylgallium (TMG) gas as a group III raw material gas, ammonia gas (NH₃), and trimethylsilane (SiH(CH₃)₃) gas as an n-type dopant gas to the base substrate 100 heated to the predetermined growth temperature. The intermediate layer 300 is grown with the c-plane as the growth surface.

In the present embodiment, the carrier concentration in the intermediate layer 300 is higher than, for example, each of the carrier concentration in the base layer 200 and the carrier concentration in the cover layer 400. In other words, the n-type impurity concentration in the intermediate layer 300 is higher than, for example, each of the n-type impurity concentration in the base layer 200 and the n-type impurity concentration in the cover layer 400. Specifically, the carrier concentration (and n-type impurity concentration) in the intermediate layer 300 is, for example, 1×10¹⁸ cm⁻³ or more, or may be 1×10¹⁹ cm⁻³ or more. Thus, in the porous step S50 described later, the intermediate layer 300 can be selectively made porous.

In the present embodiment, the thickness of the intermediate layer 300 is, for example, more than 100 nm, and may be 500 nm or more, or 1 μm or more. This allows large voids to be formed in the intermediate layer 300 in the porous step S50 described later.

### S40: Cover Layer Formation Step

After forming the intermediate layer 300, the cover layer 400 including group III nitride crystal is formed on the intermediate layer 300, for example, by the vapor phase growth method, as illustrated in FIG. 3C.

Specifically, a Si-doped GaN layer is grown as the cover layer 400 on the intermediate layer 300, for example, by the MOVPE method under the same conditions as those in the intermediate layer formation step S30 except that an amount of SiH₄ gas supplied as the n-type dopant gas is less than that in the intermediate layer formation step S30. The cover layer 400 is grown with the c-plane as the growth surface.

In the present embodiment, the carrier concentration in the cover layer 400 is lower than, for example, the carrier concentration in the intermediate layer 300. In other words, the n-type impurity concentration in the cover layer 400 is lower than, for example, the n-type impurity concentration in the intermediate layer 300. Specifically, the carrier concentration (and n-type impurity concentration) in the cover layer 400 is, for example, 1×10¹⁸ cm⁻³ or less. Thus, in the porous step S50 described later, the intermediate layer 300 can be selectively made porous while suppressing etching of the cover layer 400.

In the present embodiment, the thickness of the cover layer 400 is, for example, 10 nm or more and 2 μm or less, or may be 50 nm or more and 1.5 μm or less. Thus, the formation of voids in the intermediate layer 300 can be stably performed through the dislocations D in the cover layer 400 while suppressing peeling due to outgassing in the porous step S50 described later.

Here, in a state where the cover layer formation step S40 is completed, the base layer 200, the intermediate layer 300, and the cover layer 400 have a plurality of dislocations D passing therethrough in their thickness direction, for example. A dislocation density on the surface of the cover layer 400 is, for example, 1×10⁸ cm⁻² or more and 1×10⁹ cm⁻² or less. The dislocations D in the cover layer 400 are used in the porous step S50 below.

### S50: Porous Step

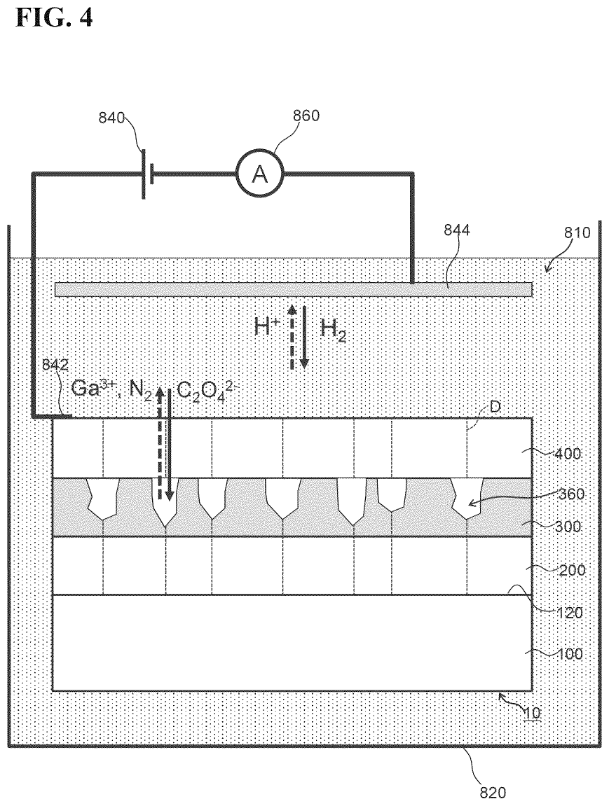

After forming the cover layer 400, as illustrated in FIG. 4, the intermediate layer 300 is made porous through the dislocations D in the cover layer 400 by performing an electrochemical process while maintaining the surface condition of the cover layer 400.

Specifically, the electrochemical process is performed, for example, by the following procedure.

As illustrated in FIG. 4, first, a process tank 820, a power source 840, and a current meter 860 are prepared. The power source 840 and the current meter 860 may be incorporated into one device as a current-voltage power source.

The process tank 820 is filled with an electrolyte 810. The electrolyte 810 is a solution containing ions capable of electrochemically etching a group III nitride. Examples of the electrolyte 810 include aqueous solutions containing oxalic acid, nitric acid, hydrofluoric acid, sulfuric acid, sodium sulfate (Na₂SO₄), sodium chloride (NaCl), sodium hydroxide (NaOH), and the like. Here, the electrolyte 810 is assumed to be an oxalic acid solution.

Furthermore, each electrode for performing the electrochemical process is prepared. Specifically, in a laminated boy obtained after the completion of the above cover layer formation step S40, the anode 842 is provided on a surface of the cover layer 400, and the anode 842 is connected to the power source 840. Meanwhile, a cathode 844 is prepared. The cathode 844 is connected to the power source 840. For the cathode 844, a material that is resistant to corrosion but allows current to flow easily is used. Specific examples of the material for the cathode 844 include stainless steel (SUS), platinum (Pt), gold (Au), and boron-doped diamond.

After the connection of each electrode is completed, the cathode 844 and the laminated body with the anode 842 connected thereto are immersed into the electrolyte 810 in the process tank 820. In this state, a predetermined voltage is applied between the anode 842 and the cathode 844 by the power source 840. Thereby, the electrochemical process is performed. At this time, the progress of the electrochemical process is checked based on changes in the current at the current meter 860.

At this time, by performing the electrochemical process, the electrolyte containing C₂O₄²⁻ is allowed to penetrate the dislocations D in the cover layer 400, which has a relatively low carrier concentration, toward the intermediate layer 300, which has a relatively high carrier concentration. That is, the dislocation D in the cover layer 400 is used as a nano-sized path through which the electrolyte penetrates. The electrolyte having reached the intermediate layer 300 in this way selectively etches the intermediate layer 300. This creates a plurality of voids 360 near the plurality of dislocations D in the intermediate layer 300. As a result, the intermediate layer 300 can be made porous.

On the other hand, according to the following reaction equation, group III element ions (Ga³⁺) and nitrogen (N₂) gas produced when etching the intermediate layer 300 are released through the dislocations D in the cover layer 400 to the outside of the cover layer 400.

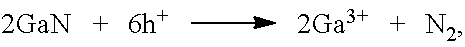

where “h⁺” is a positive charge.

At this time, in the present embodiment, the length of each of the plurality of voids 360 in the intermediate layer 300 in the direction along the main surface 120 of the base substrate 100 is, for example, 30 nm or more, or may be 100 nm or more, when viewed in any cross section orthogonal to the main surface 120 of the base substrate 100.

At this time, in the present embodiment, the length of each of the plurality of voids 360 in the intermediate layer 300 in the direction along the main surface 120 of the base substrate 100 is, for example, 30 nm or more, or may be 100 nm or more, when viewed in a cross section along the main surface of the base substrate 100 and at a depth of 30 nm below the bottom surface of the cover layer 400.

At this time, in the present embodiment, the depth of each of the plurality of voids 360 in the thickness direction of the intermediate layer 300 is, for example, more than 100 nm, and may be 500 nm or more, or 1 μm or more.

By forming such voids 360 in the intermediate layer 300, the voids 360 in the intermediate layer 300 can be maintained in the regrowth step S60 described later.

Meanwhile, in the electrochemical process, almost no etching occurs on the surface of the cover layer 400 having a relatively low carrier concentration. Thus, the surface condition of the cover layer 400 is allowed to be maintained flat.

At this time, in the present embodiment, after the porous step S50, the Ra of the surface of the cover layer 400 is, for example, 1.0 nm or less, and the RMS of the surface of the cover layer 400 is, for example, 2.0 nm or less. Alternatively, the Ra of the surface of the cover layer 400 may be, for example, 0.5 nm or less, and the RMS of the surface of the cover layer 400 may be, for example, 1.0 nm or less. Here, the Ra and RMS are values obtained when the surface of the cover layer 400 is observed with the AFM in the field of view of 5 μm square.

By maintaining a small surface roughness of the cover layer 400 as described above, a thick regrowth layer 500 with good crystallinity can be stably grown on the cover layer 400.

Specific conditions for the electrochemical process that can implement selective etching of the intermediate layer 300 described above are, for example, as follows. The processing voltage is adjusted based on the carrier concentration of the intermediate layer 300 or the like. The processing current is adjusted based on a process area (an area of the base substrate 100). The processing time is adjusted based on the thickness of the intermediate layer 300.

Electrolyte temperature: room temperature (10° C. or higher and 30° C. or lower)
Processing voltage: 1 V or more and 200 V or less, or 10 V or more and 20 V or less
Processing current: 0.01 mA or more and 60 A or less, or 0.1 mA or more and 10 A or less
Processing time: 0.1 min or more and 180 min or less, or 1 min or more and 30 min or less

The above electrochemical process forms the seed substrate 10 for nitride crystal growth.

After the electrochemical process, the seed substrate 10 for nitride crystal growth is removed from the electrolyte in the process tank 820. Thereafter, the seed substrate 10 for nitride crystal growth that has been removed from the process tank 820 is washed with pure water or the like and dried. Consequently, the electrolyte remaining in the voids 360 of the intermediate layer 300 is removed. In the way above, the porous step $50 is completed.

In this way, the seed substrate 10 for nitride crystal growth of the present embodiment illustrated in FIG. 1 is obtained. The seed substrate 10 for nitride crystal growth is used for the regrowth step S60 and the peeling step S70 described later.

### S60: Regrowth Step

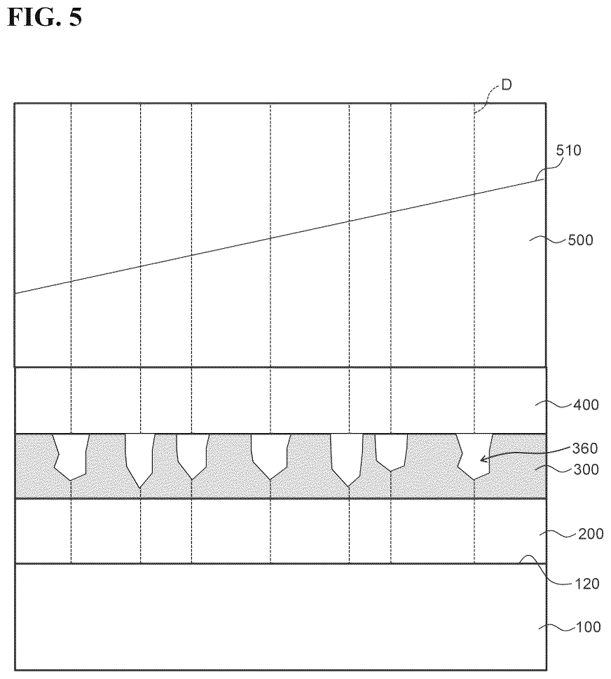

After the porous step S50 is completed, as illustrated in FIG. 5, the regrowth layer 500 comprising group III nitride crystal is epitaxially grown on the cover layer 400. The growing method of the regrowth layer 500 uses, for example, the vapor phase growth method.

Specifically, a GaN layer is grown, for example, using the HVPE method by supplying GaCl gas and NH₃ gas to the seed substrate 10 for nitride crystal growth heated to a predetermined growth temperature. The growth temperature of each layer is, for example, 1000° C. or higher and 1100° C. or lower. In the way above, the GaN layer is epitaxially grown on the surface of the cover layer 400 as the regrowth layer 500. Various dopants may be added to the GaN layer as the regrowth layer 500.

At this time, in the present embodiment, by starting the growth of the regrowth layer 500 on the cover layer 400 with a flat surface, the regrowth layer 500 can be grown with a c-plane 510 as the growth surface, without generating crystal planes (inclined interfaces) other than the c-plane 510. That is, the regrowth layer 500 can be grown in a step-flow growth mode over the entire surface of the cover layer 400, instead of growing a regrowth layer in a three dimensional manner as in the VAS method. Thus, the crystallinity of the regrowth layer 500 can be improved. The c-axis, which is the normal of the c-plane 510 of the regrowth layer 500, may be inclined at an off-angle inherited from the c-axis of the base substrate 100, which is inclined at a specified off-angle.

At this time, in the present embodiment, the thickness of the regrowth layer 500 is, for example, 600 μm or more, and may be 1 mm or more. The upper limit of the thickness of the regrowth layer 500 is not particularly limited. However, from the viewpoint of improving productivity, the thickness of the regrowth layer 500 may be, for example, 100 mm or less.

Here, the regrowth layer 500 has a plurality of dislocations D inherited from the cover layer 400. However, the positions of the dislocations D in the regrowth layer 500 move in a random walk manner as the thick regrowth layer 500 grows. Thus, the dislocations D are caused to gather or to form loops during the growth of the regrowth layer 500. Such a phenomenon reduces the number of dislocations reaching the surface of the thick regrowth layer 500. As a result, the dislocation density of the regrowth layer 500 can be reduced. (Note that the number of dislocations in FIG. 5 has not been reduced due to simplification of FIG. 5.)

As a result, in the present embodiment, the dislocation density at the surface of the regrowth layer 500 can be, for example, 3×10⁷ cm⁻² or less, 1×10⁷ cm⁻² or less, or 5×10⁶ cm⁻² or less. The upper limit of the dislocation density at the surface of the regrowth layer 500 depends on the thickness of the regrowth layer 500.

### S70: Peeling Step

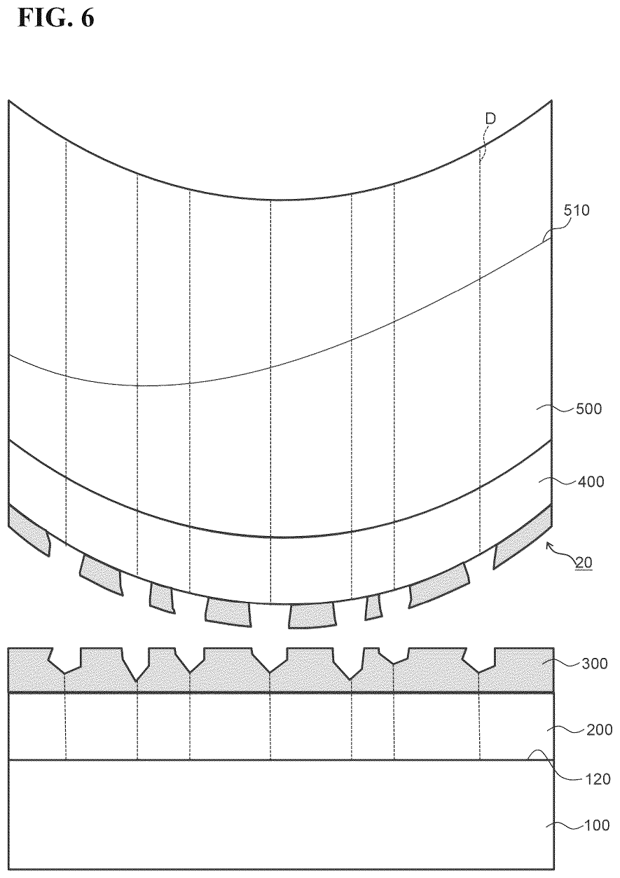

After the regrowth step S60 is completed, as illustrated in FIG. 6, the regrowth layer 500 is peeled off from the base substrate 100 by using at least a portion of the intermediate layer 300 made porous as the boundary.

In the present embodiment, the regrowth layer 500 is peeled off spontaneously from the base substrate 100 while decreasing the temperature after the regrowth step S60.

Here, in the regrowth step S60, tensile stress is generated in the regrowth layer 500 (in the direction along the main surface 120 of the base substrate 100). This is due to the fact that, for example, the dislocation density decreases as the thickness of the regrowth layer 500 increases, as described above.

The tensile stress generated in the regrowth layer 500 in this way warps the c-plane 510 of the regrowth layer 500 into a spherical shape with an upper side thereof recessed. Thus, the regrowth layer 500 is peeled off spontaneously and gradually from an outer periphery of the base substrate 100 toward a center thereof. As a result, the regrowth layer 500 with a large area can be peeled off easily and stably.

By the above peeling step S70, a peeled intermediate 20 including at least the cover layer 400 and the regrowth layer 500 is formed. Residual fragments of the intermediate layer 300 may remain on a bottom surface of the cover layer 400 of the peeled intermediate 20.

### S80: Post-Process Step

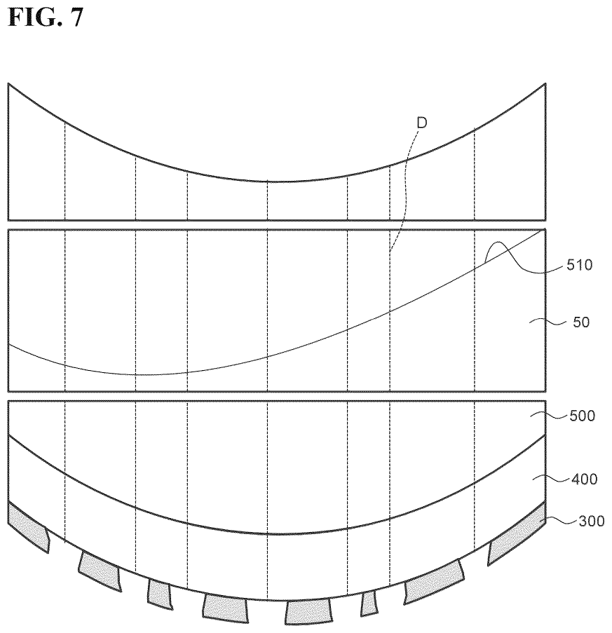

After the peeling step S70 is completed, the regrowth layer 500 is sliced by a wire saw, for example, along a cutting plane perpendicular to a normal direction at the center of the surface of the regrowth layer 500, as illustrated in FIG. 7. This forms a nitride crystal substrate 50 (hereinafter abbreviated as the “substrate 50”) as an as-sliced substrate.

Next, both surfaces of the substrate 50 are polished by a polishing device. Thus, the main surfaces of the substrate 50 becomes mirror-finished.

Through the steps described above, the substrate 50 comprising single crystal of a group III nitride of the present embodiment is obtained.

The diameter of the substrate 50 is, for example, 2 inches or more, or may be 4 inches or more. The thickness of the substrate 50 is, for example, 150 μm or more and 3 mm or less.

### (3) Summary of Present Embodiment

According to the present embodiment, one or more of the following effects can be obtained.

(a) In the porous step S50 of the present embodiment, the intermediate layer 300 is made porous through the dislocations D in the cover layer 400 by performing the electrochemical process while maintaining the surface condition of the cover layer 400. In the regrowth step S60, the regrowth layer 500 is epitaxially grown on the cover layer 400.

Here, in Comparative Example 1, a description is given of a case where the regrowth layer 500 is grown directly on the porous intermediate layer 300 without forming the cover layer 400. In Comparative Example 1, when the regrowth layer 500 is grown, the voids 360 in the intermediate layer 300 are embedded with the regrowth layer 500. Thus, the voids 360 that may trigger peeling of the regrowth layer 500 disappear. As a result, it becomes difficult to peel the regrowth layer 500 from the base substrate 100.

In contrast, in the present embodiment, the electrochemical process is performed in a state where the cover layer 400 having a relatively low carrier concentration covers the intermediate layer 300 having a relatively high carrier concentration, as described above. Thus, the intermediate layer 300 can be selectively porous through the dislocations D in the cover layer 400 while maintaining the surface condition of the cover layer 400.

By maintaining the surface condition of the cover layer 400 on the porous intermediate layer 300 to be flat, the thick regrowth layer 500 with good crystallinity can be stably grown by using the cover layer 400 as the regrowth base substrate in the regrowth step S60.

Meanwhile, since the flat cover layer 400 covers the plurality of voids 360 in the intermediate layer 300, the voids 360 in the intermediate layer 300 are prevented from being embedded in the regrowth step S60, so that the voids 360 in the intermediate layer 300 can be maintained. Thereafter, the regrowth layer 500 can be peeled off easily and stably from the base substrate 100 by using, as the boundary, at least a portion of the intermediate layer 300 maintained in the porous state.

In the way above, according to the present embodiment, the substrate 50 comprising single crystal of a group III nitride can be easily obtained from the peeled regrowth layer 500.

(b) In the seed substrate 10 for nitride crystal growth, obtained after the porous step S50 of the present embodiment, the Ra of the surface of the cover layer 400 is 1.0 nm or less, and the RMS of the surface of the cover layer 400 is 2.0 nm or less. That is, even when the cover layer 400 has the plurality of dislocations D as described above, the surface condition of the cover layer 400 is maintained to be flat. Thus, the thick regrowth layer 500 with good crystallinity can be stably grown on the cover layer 400, as described above.

(c) In the intermediate layer formation step S30 of the present embodiment, the thickness of the intermediate layer 300 is more than 100 nm. Thus, the large voids 360 can be formed in the intermediate layer 300 in the porous step S50.

Here, as Comparative Example 2, a description is given of the literature Fabien C.-P. Massabuau et al, APL Mater. 8, 031115 (2020). In Comparative Example 2, multiple layers of high n-doped layers and low n-doped layers are alternately laminated. Next, the electrochemical process was performed on the laminated layers. Thus, a Distributed Bragg Reflector (DBR) having a plurality of porous highly n-doped layers and low n-doped layers is formed. The thickness of each of the porous high n-doped layers and low n-doped layers was about ¼ times the wavelength of light incident on the DBR, for example, 100 nm or less.

However, in Comparative Example 2, if a regrowth layer is grown on the DBR, the porous highly n-doped layer is crushed, causing the voids in the highly n-doped layer to disappear at the growth temperature during regrowth. This makes it difficult to use the DBR as a sacrificial layer for peeling off the regrowth layer from the substrate.

In contrast, in the present embodiment, by setting the thickness of the intermediate layer 300 to more than 100 nm, large voids 360 can be formed in the intermediate layer 300, as described above. Thus, in the regrowth step S60, the collapse of the intermediate layer 300 can be suppressed, and thereby the voids 360 in the intermediate layer 300 can be maintained. As a result, the regrowth layer 500 can be easily and stably peeled off from the base substrate 100 by using, as the boundary, at least a portion of the intermediate layer 300 maintained in a porous state.

(d) In the porous step S50 of the present embodiment, the length of each of the plurality of voids 360 in the intermediate layer 300 in the direction along the main surface 120 of the base substrate 100 is, for example, 30 nm or more, when viewed in any cross section orthogonal to the main surface 120 of the base substrate 100.

Furthermore, in the porous step S50 of the present embodiment, the length of each of the plurality of voids 360 in the intermediate layer 300 in the direction along the main surface 120 of the base substrate 100 is, for example, 30 nm or more, when viewed in the cross section along the main surface of the base substrate 100 and at a depth of 30 nm below the bottom surface of the cover layer 400.

Thus, in the regrowth step S60, the voids 360 in the intermediate layer 300 can be maintained without disappearing, even when there is a minor collapse of the voids 360 in the direction along the main surface 120 of the base substrate 100. As a result, as in (c), the regrowth layer 500 can be easily and stably peeled off from the base substrate 100.

(e) In the porous step S50 of the present embodiment, the depth of each of the plurality of voids 360 in the thickness direction of the intermediate layer 300 is, for example, more than 100 nm. Thus, in the regrowth step S60, the voids 360 in the intermediate layer 300 can be maintained without disappearing, even when there is a minor collapse of the voids 360 in the thickness direction (depth direction) of the intermediate layer 300. As a result, as in (c) and (d), the regrowth layer 500 can be easily and stably peeled off from the base substrate 100.

(f) In the cover layer formation step S40 of the present embodiment, the thickness of the cover layer 400 is 10 nm or more and 2 μm or less.

When the thickness of the cover layer 400 is less than 10 nm, the cover layer 400 may be peeled off easily from the intermediate layer 300 due to outgassing of N₂ gas or the like generated when etching the intermediate layer 300 in the porous step S50.

In contrast, in the present embodiment, the cover layer 400 can discharge gas generated by outgassing toward the outside of the cover layer 400 through the dislocations D of the cover layer 400 while maintaining the cover layer 400 itself by setting the thickness of the cover layer 400 to 10 nm or more, even when the outgassing of N₂ gas or the like occurs during etching of the intermediate layer 300 in the porous step S50. Thus, the cover layer 400 can be prevented from being peeled off from the intermediate layer 300.

On the other hand, the cover layer 400 with a thickness of more than 2 μm makes it difficult to allow the electrolyte to reach the intermediate layer 300 through the dislocations D in the cover layer 400 in the porous step S50. Thus, it becomes difficult to form the voids 360 in the intermediate layer 300.

In contrast, in the present embodiment, by setting the thickness of the cover layer 400 to 2 μm or less, the electrolyte is allowed to reach the intermediate layer 300 through the dislocations D in the cover layer 400 in the porous step S50. Thus, the voids 360 can be formed stably in the intermediate layer 300.

(g) In the peeling step S70 of the present embodiment, the regrowth layer 500 is peeled off spontaneously from the base substrate 100 while decreasing the temperature after the regrowth step S60.

Here, as another method different from the method of the present embodiment, for example, a dummy substrate transfer method is proposed. In the dummy substrate transfer method, a dummy substrate is attached to the regrowth layer 500, and the regrowth layer 500 is mechanically peeled off from the base substrate 100, together with the dummy substrate. However, steps of the dummy substrate transfer method become complicated because this method involves dummy substrate attachment, mechanical peeling, and dummy substrate removal.

In contrast, in the present embodiment, the regrowth layer 500 is peeled off spontaneously from the base substrate 100, eliminating the need for a special separate step. That is, the production method can be simplified.

(h) In the peeling step S70 of the present embodiment, the c-plane 510 is warped into a spherical shape with an upper side thereof recessed by tensile stress generated in the regrowth layer 500, thereby spontaneously peeling off the regrowth layer 500 from the outer periphery of the base substrate 100 toward a center thereof.

Here, in the dummy substrate transfer method described above, it is difficult to peel off the regrowth layer 500 evenly from the base substrate 100 because the degree of mechanical peeling using the dummy substrate depends on an operator's force.

In contrast, in the present embodiment, by utilizing the warpage of the c-plane 510 of the regrowth layer 500, the regrowth layer 500 can be gradually peeled off from the outer periphery of the base substrate 100 toward its center. In other words, the regrowth layer 500 can be peeled off evenly in a concentric manner with respect to the center of the base substrate 100. As a result, the regrowth layer 500 with a large area can be peeled off easily and stably.

### Other Embodiments of Present Disclosure

The embodiments of the present disclosure have been specifically described above. However, the present disclosure is not limited to the embodiments described above, and can be modified in various ways without departing from its gist.

In the embodiments described above, the base layer formation step S20 is performed, but the base layer formation step S20 may not be performed. That is, the base layer 200 may be eliminated. In the intermediate layer formation step S30, the intermediate layer 300 may be formed directly on the base substrate 100.

In the embodiments described above, a top layer of the base layer 200, the intermediate layer 300, the cover layer 400, and the regrowth layer 500 each include GaN crystal, but the present disclosure is not limited to this case. Each layer is not limited to GaN crystal, but may include, for example, group III nitride crystal such as aluminum nitride (AlN), aluminum gallium nitride (AlGaN), indium nitride (InN), indium gallium nitride (InGaN), and aluminum indium gallium nitride (AlInGaN), that is, crystal represented by a composition formula of InₓAl_{y}Ga_{1-x-y}N (0≤x≤1, 0≤y≤1, 0≤x+y≤1).

In the embodiments described above, the Ra of the main surface 120 of the base substrate 100 is less than 0.3 nm, but the main surface 120 of the base substrate 100 may be patterned to have, for example, periodic unevenness. The base substrate 100 may be, for example, a so-called Patterned Sapphire Substrate (PSS).

In the embodiments above, it has been described that the base substrate 100 may be a free-standing substrate comprising a group III nitride (e.g., GaN free-standing substrate). The free-standing substrate comprising a group III nitride as the base substrate 100 may be reused, for example, after peeling off a functional layer for a semiconductor device, grown by so-called GaN on GaN, as in the following modification example.

In the modification example, first, in the base substrate preparation step S10, a free-standing substrate comprising a group III nitride is prepared as the base substrate 100. After the base substrate preparation step S10, as in the above embodiment, the processes from the base layer formation step S20 to the porous step S50 are performed. Next, in the regrowth step S60, a functional layer is grown as the regrowth layer 500. The term “functional layer” as used herein means a layer functioning as at least a part of the semiconductor device. In the peeling step S70, the functional layer is peeled off as the regrowth layer 500. Next, after the peeling step S70, a polishing step is performed to polish a surface of the remaining base substrate 100. After the polishing step, the base substrate 100 is reused, allowing for the repetition of a cycle from the base layer formation step S20 to the polishing step. Thus, in the modification example, the free-standing substrate comprising a group III nitride as the base substrate 100 can be reused, leading to a reduction in the manufacturing costs of semiconductor devices.

In the embodiments described above, the top layer of the base layer 200, the intermediate layer 300, the cover layer 400, and the regrowth layer 500 contain the same GaN crystal, but at least any one of the top layer of the base layer 200, the intermediate layer 300, the cover layer 400, and the regrowth layer 500 may contain group III nitride crystal different from those of the other layers.

In the embodiments described above, the top layer of the base layer 200, the intermediate layer 300, the cover layer 400, and the regrowth layer 500 each contain Si as the n-type dopant, but at least any one of the top layer of the base layer 200, the intermediate layer 300, the cover layer 400, and the regrowth layer 500 may contain, for example, germanium (Ge) as the n-type dopant.

In the embodiments described above, the above-mentioned respective vapor phase growth methods are used as growth methods for the base layer 200, intermediate layer 300, cover layer 400, and regrowth layer 500, but the present disclosure is not limited to this case. The MOVPE, HVPE, HVPE, and MOVPE methods may be used as the growth methods for the base layer 200, intermediate layer 300, cover layer 400, and regrowth layer 500, respectively. Alternatively, a growth method other than the vapor phase growth method may be used as the growth method for at least any one of the base layer 200, intermediate layer 300, cover layer 400, and regrowth layer 500.

### EXAMPLES

The following is a description of experimental results that support effectiveness of the above-mentioned embodiments.

### (1) Fabrication of Seed Substrate for Nitride Crystal Growth and Peeled Intermediate

In Samples A1 to A6 and Samples B1 to B3, seed substrates for nitride crystal growth were fabricated under the conditions outlined in Tables 1 and 2 and described below. In Samples A1 to A6, the regrowth layer step and the peeling step were performed using the seed substrates for nitride crystal growth.

### Base Substrate

In sample A1, the following substrate was used as the base substrate for obtaining a seed substrate for nitride crystal growth.
Base substrate: Sapphire substrate
Surface orientation of main surface of base substrate: +c-plane
Diameter of base substrate: 4 inches (100.0 mm)
Thickness of base substrate: 650 μm

In each of Samples A2 to A6 and Samples B1 to B3, the following substrate was used as the base substrate for obtaining the seed substrate for nitride crystal growth.
Base substrate: Sapphire substrate
Surface orientation of main surface of base substrate: +c-plane
Diameter of base substrate: 2 inches (50.8 mm)
Thickness of base substrate: 430 μm

### Samples A1 and A4

In sample A1, as shown in Table 1 described later, an AlN buffer layer and a Si-doped GaN layer were formed as the base layer on the substrate in this order by the HVPE method under the following conditions.
Growth temperature of base layer: 1055° C.
Thicknesses of AlN buffer layer and GaN layer: 100 nm and 4 μm, respectively
Carrier concentration in GaN layer as base layer: 2.2×10¹⁶ cm⁻³

Next, a Si-doped GaN layer was grown as the intermediate layer on the base layer by the MOVPE method under the following conditions.
Growth temperature of intermediate layer: 1000° C.
Thickness of intermediate layer: 1 μm
Carrier concentration in intermediate layer: 1.6×10¹⁹ cm⁻³

Next, a Si-doped GaN layer was grown as the cover layer above the base layer by the MOVPE method under the following conditions.
Growth temperature of cover layer: 1000° C.
Thickness of cover layer: 1 μm
Carrier concentration in cover layer: 3.1×10¹⁷ cm⁻³

Next, the intermediate layer was made porous through dislocations in the cover layer by performing an electrochemical process under the following conditions. Consequently, seed substrates for nitride crystal growth were obtained. Specifically, two seed substrates for nitride crystal growth were fabricated, one for observation and the other for regrowth.
Electrolyte temperature: room temperature (23° C.)
Process voltage: 50 V
Processing current: maximum 100 mA
Processing time: 6 min

Next, a GaN layer was grown as the regrowth layer on the cover layer by the HVPE method under the following conditions.
Growth temperature of regrowth layer: 1055° C.
Thickness of regrowth layer: 200 μm

The regrowth layer was peeled off from the base substrate while its temperature was decreased after the regrowth.

In Sample A4, as shown in Table 2 described later, the regrowth step and the peeling step were performed using the seed substrate for nitride crystal growth in the same manner as in Sample A1, except that the diameter of the base substrate was 2 inches and the thickness of the regrowth layer was 800 μm.

### Samples A2, A3, A5, and A6

In Samples A2 and A3, as shown in Table 1 described later, seed substrates for nitride crystal growth were fabricated under different conditions from Sample A1 in terms of the diameter of the base substrate, the growth method and thickness of the intermediate layer, and the growth method and thickness of the cover layer. Thereafter, the regrowth step and the peeling step were performed in the same manner as in Sample A1.

In Samples A5 and A6, as shown in Table 2 described later, the regrowth step and the peeling step were performed using the respective seed substrates for nitride crystal growth in the same manner as in Samples A2 and A3, except that the thickness of the regrowth layer was 800 μm.

### Sample B1

In Sample B1, as shown in Table 1 described later, a seed substrate for nitride crystal growth was fabricated in the same manner as in Sample A1, except that the diameter of the base substrate was 2 inches and the cover layer was not formed. In Sample B1, the regrowth step was performed in the same manner as in Sample A1.

### Sample B2

In Sample B2, as shown in Table 1 described later, a seed substrate for nitride crystal growth was fabricated in the same manner as in Sample A2, except that the growth method and thickness of the intermediate layer and the growth method and thickness of the cover layer were different from those of Sample A2. In Sample B2, a subsequent process was not performed after the regrowth step.

### Sample B3

In Sample B3, as shown in Table 1 described later, a seed substrate for nitride crystal growth was fabricated in the same manner as in Sample A1, except that the diameter of the base substrate, the thickness of the intermediate layer, and the thickness of the cover layer were different from those of Sample A1. In Sample B3, the regrowth step was performed in the same manner as in Sample A1.

### (2) Evaluation

An evaluation was performed on each sample as follows.

### Optical Microscope

Regarding the seed substrates for nitride crystal growth of Samples B1 to B3 and laminated bodies of Samples B1 and B2 obtained after the regrowth step, their surfaces or cross sections were observed with an optical microscope as an external inspection.

### AFM

Regarding the seed substrates for nitride crystal growth of Samples A1 to A6, surfaces of their cover layers were observed with the AFM in the field of view of 5 μm square.

### Scanning Electron Microscope (SEM)

Regarding Samples A1 to A6, cross sections of the seed substrates for nitride crystal growth and their cross sections obtained after peeling off the regrowth layer were observed with the SEM as the cross sections perpendicular to the main surface of the base substrate.

### (3) Results

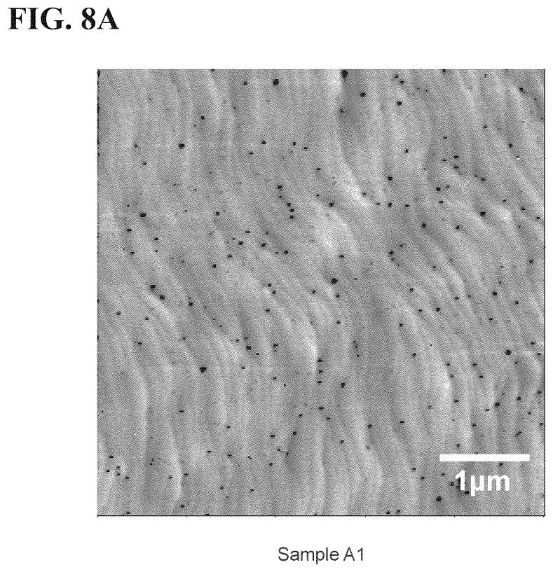

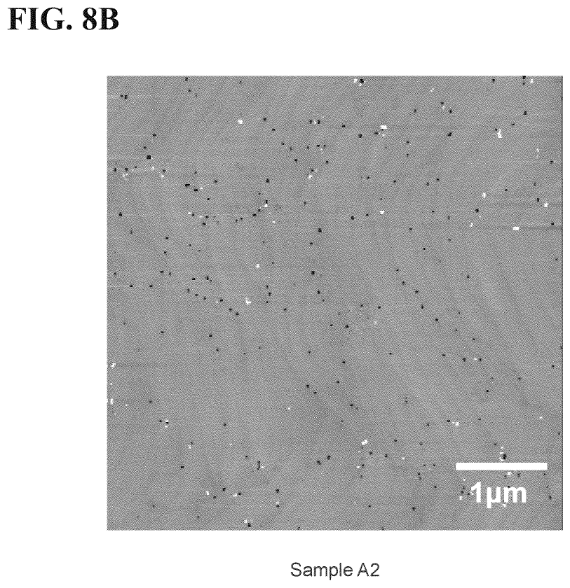

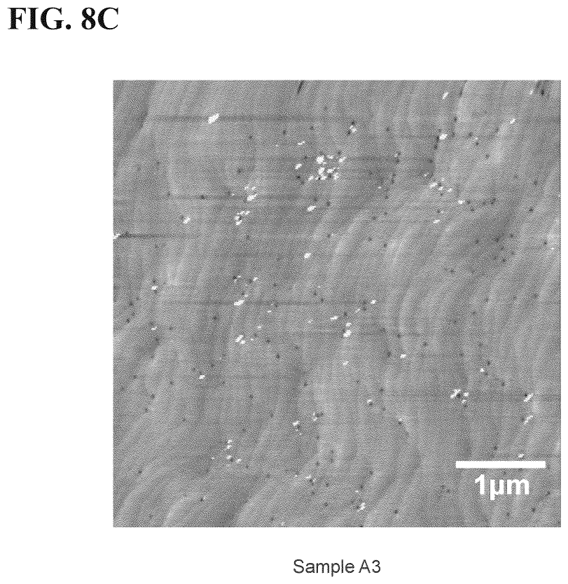

The evaluation results will be described referring to Tables 1 and 2 and FIGS. 8A to 11.

TABLE 1

| SAMPLE | | A1 | A2 | A3 | B1 | B2 | B3 |
|---|---|---|---|---|---|---|---|
| DIAMETER OF BASE SUBSTRATE | | 4 inches | 2 inches | 2 inches | 2 inches | 2 inches | 2 inches |
| INTERMEDIATE LAYER | GROWTH METHOD | MOVPE | HVPE | HVPE | MOVPE | MOVPE | MOVPE |
| | THICKNESS (nm) | 1000 | 600 | 600 | 1000 | 500 | 50 |
| COVER LAYER | GROWTH METHOD | MOVPE | HVPE | HVPE | MOVPE | MOVPE | MOVPE |
| | THICKNESS (nm) | 1000 | 100 | 100 | NONE | 5 | 500 |
| ELECTROCHEMICAL | VOLTAGE (V) | 50 | 20 | 20 | 50 | 20 | 50 |
| PROCESS | TIME (min) | 6 | 10 | 20 | 6 | 10 | 6 |
| SURFACE OF COVER | Ra (nm) | 0.220 | 0.266 | 0.274 | — | COVER LAYER | NOT |
| LAYER AFTER | | | | | | PARTIALLY | MEASURED |
| ELECTROCHEMICAL | RMS (nm) | 0.313 | 0.725 | 0.588 | — | PEELED | NOT |
| PROCESS | | | | | | | MEASURED |

| | | | | | | |
|---|---|---|---|---|---|---|
| REGROWTH STEP | POSSIBLE | POSSIBLE | POSSIBLE | VOIDS | — | VOIDS |
| | | | | EMBEDDED | | DISAPPEARED |
| THICKNESS OF REGROWTH LAYER | 200 μm | 200 μm | 200 μm | 200 μm | 200 μm | 200 μm |
| PEELING STEP | PEELING | PEELING | PEELING | PEELING | — | PEELING |
| | POSSIBLE | POSSIBLE | POSSIBLE | IMPOSSIBLE | | IMPOSSIBLE |

TABLE 2

| SAMPLE | | A4 | | A5 | | A6 | |
|---|---|---|---|---|---|---|---|
| SEED | DIAMETER OF | 2 | inches | 2 | inches | 2 | inches |

| | | | | |
|---|---|---|---|---|
| SUBSTRATE | BASE SUBSTRATE | | | |
| | OTHER CONFIGURATIONS | THE SAME AS IN | THE SAME AS IN | THE SAME AS IN |
| | | SAMPLE A1 | SAMPLE A2 | SAMPLE A3 |

| REGROWTH STEP | POSSIBLE | | POSSIBLE | | POSSIBLE | |
|---|---|---|---|---|---|---|
| THICKNESS OF REGROWTH LAYER | 800 | μm | 800 | μm | 800 | μm |

| PEELING STEP | PEELING | PEELING | PEELING |
|---|---|---|---|
| | POSSIBLE | POSSIBLE | POSSIBLE |

### Sample B1

In Sample B1, the cover layer was not formed, and thus the regrowth step was performed with the porous intermediate layer exposed. Thus, the voids in the intermediate layer were embedded by the regrowth layer. As a result, the regrowth layer could not be peeled off from the substrate.

### Sample B2

In Sample B2, a part of the cover layer was peeled off after the electrochemical process. Since the thickness of the cover layer was less than 10 nm in Sample B2, it is considered that the cover layer was peeled off due to outgassing of gas generated by the electrochemical process.

### Sample B3

In Sample B3, the voids in the intermediate layer disappeared after the regrowth step. This is considered to be because the porous intermediate layer collapsed at the growth temperature during the regrowth. As a result, the regrowth layer could not be peeled off from the base substrate.

### Sample A1 to A6

The cover layer in each of the seed substrates for nitride crystal growth of Samples A1 to A3 was observed with the AFM. As a result, as illustrated in FIGS. 8A to 8C, dislocations were observed in the cover layer; however, the overall surface condition of the cover layer remained flat. As shown in Table 1, the Ra of the surface of the cover layer was 0.5 nm or less, and the RMS of the surface of the cover layer was 1.0 nm or less.

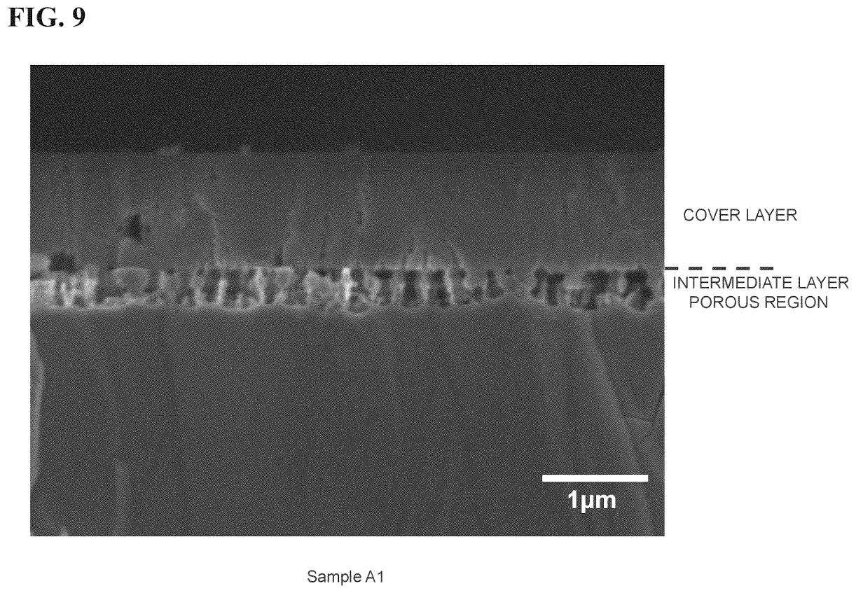

The cross section of the seed substrate for nitride crystal growth of Sample A1 was observed with the SEM. As a result, as illustrated in FIG. 9, the intermediate layer was selectively formed in a porous shape. The length of each void in the cross section perpendicular to the main surface of the base substrate was 80 nm or more and 400 nm or less. The depth of the void in the thickness direction of the intermediate layer was about 420 nm.

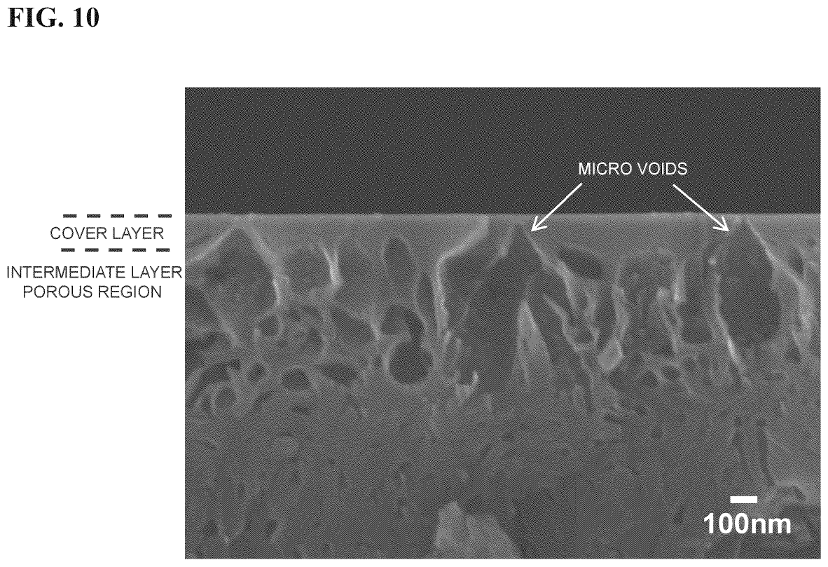

The cross section of each of the seed substrates for nitride crystal growth of Samples A2 and A3 was observed with the SEM. As a result, although not illustrated, the intermediate layer was selectively formed in a porous shape, as in Sample A1. Note that in Samples A2 and A3, micro voids were observed below the surface of the cover layer, as illustrated in FIG. 10. However, the micro voids did not reach the surface of the cover layer.

In the regrowth step of Samples A1 to A3, the regrowth layer could be grown more stably than in Samples B1 and B3.

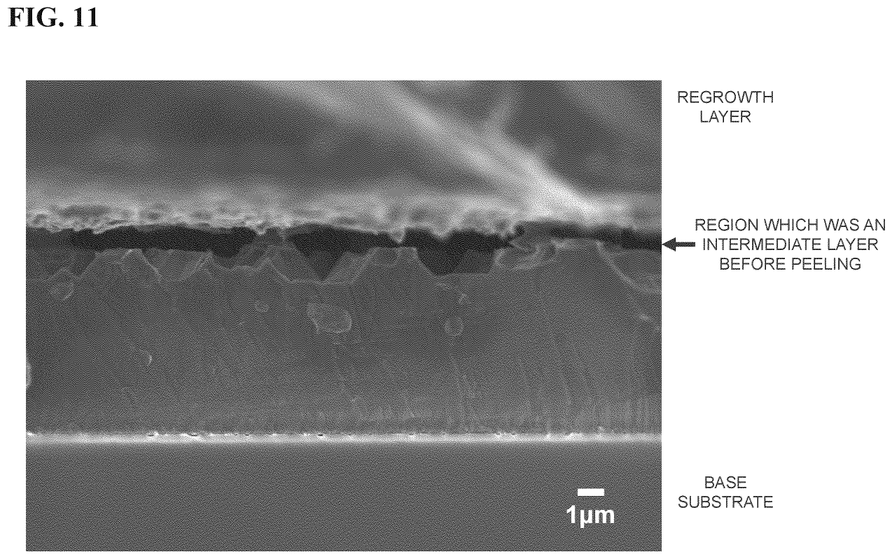

The cross section of each of Sample A1 to A3 from which the regrowth layer was peeled off was observed with the SEM. As a result, as illustrated in FIG. 11, the regrowth layer is peeled off from the base substrate by using the porous intermediate layer as the boundary.

It is confirmed that the observed results of Samples A4 to A6, where the thickness of the regrowth layer was 800 μm, were equivalent to those of Samples A1 to A3, respectively.

### SUMMARY

According to Samples A1 to A6 to which the method of the present disclosure was applied, it is confirmed that the regrowth layer could be stably grown and easily peeled off.

### Supplementary Descriptions

Hereinafter, aspects of the present disclosure will be supplementarily described.

### Supplementary Description 1

A seed substrate for nitride crystal growth, comprising:
a base substrate;
an intermediate layer provided above the base substrate and including n-type group III nitride crystal; and
a cover layer provided on the intermediate layer and including group III nitride crystal having a carrier concentration lower than a carrier concentration of the intermediate layer, wherein
the intermediate layer is porous,
a surface of the cover layer has an arithmetic mean roughness of 1.0 nm or less, and
the surface of the cover layer has a root mean square roughness of 2.0 nm or less,
the arithmetic mean roughness and the root mean square roughness being values obtained when the surface of the cover layer is observed with an atomic force microscope in a field of view of 5 μm square.

### Supplementary Description 2

The seed substrate for nitride crystal growth according to the supplementary description 1, wherein the intermediate layer has a thickness of more than 100 nm.

### Supplementary Description 3

The seed substrate for nitride crystal growth according to the supplementary description 1 or 2, wherein the intermediate layer includes a plurality of voids, and
a length of each of the plurality of voids in the intermediate layer in a direction along a main surface of the base substrate is 30 nm or more, when viewed in any cross section orthogonal to the main surface of the base substrate.

### Supplementary Description 4

The seed substrate for nitride crystal growth according to any one of the supplementary descriptions 1 to 3, wherein
the intermediate layer includes a plurality of voids, and
a length of each of the plurality of voids in the intermediate layer in a direction along a main surface of the base substrate is 30 nm or more, when viewed in the cross section along the main surface of the base substrate and at a depth of 30 nm below a bottom surface of the cover layer.

### Supplementary Description 5

The seed substrate for nitride crystal growth according to any one of the supplementary descriptions 1 to 4, wherein
the intermediate layer includes a plurality of voids, and
a depth of each of the plurality of voids in a thickness direction of the intermediate layer is more than 100 nm.

### Supplementary Description 6

The seed substrate for nitride crystal growth according to any one of the supplementary descriptions 1 to 5, wherein
the cover layer has a thickness of 10 nm or more and 2 μm or less.

### Supplementary Description 7

The seed substrate for nitride crystal growth according to any one of the supplementary descriptions 1 to 6, wherein
the intermediate layer includes a plurality of voids, and
the plurality of voids in the intermediate layer extends from a bottom surface of the cover layer toward the base substrate.

### Supplementary Description 8

The seed substrate for nitride crystal growth according to any one of the supplementary descriptions 1 to 7, wherein
the intermediate layer includes a plurality of voids, and
each of the plurality of voids in the intermediate layer is formed at a position overlapping each of a plurality of dislocations in the cover layer.

### Supplementary Description 9

The seed substrate for nitride crystal growth according to any one of the supplementary descriptions 1 to 8, wherein
the base substrate has a diameter of 2 inches or more.

### Supplementary Description 10

The seed substrate for nitride crystal growth according to any one of the supplementary descriptions 1 to 9, further comprising:
a base layer provided between the base substrate and the intermediate layer and including group III nitride crystal having a carrier concentration lower than a carrier concentration of the intermediate layer.

### Supplementary Description 11

A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary.

### Supplementary Description 12

The production method for a nitride crystal substrate according to the supplementary description 11, wherein in (f), the regrowth layer is peeled off spontaneously from the base substrate while decreasing the temperature after (e).

### Supplementary Description 13

The production method for a nitride crystal substrate according to the supplementary description 11 or 12, wherein in (e), the regrowth layer is grown with (0001) as a growth surface.

### Supplementary Description 14

The production method for a nitride crystal substrate according to the supplementary description 13, wherein in (f), the (0001) is warped into a spherical shape with an upper side thereof recessed by tensile stress in a direction along a main surface of the base substrate, generated in the regrowth layer, thereby spontaneously peeling off the regrowth layer from an outer periphery of the base substrate toward a center thereof.

### Supplementary Description 15

The production method for a nitride crystal substrate according to any one of the supplementary descriptions 11 to 14, wherein in (a), a free-standing substrate comprising a group III nitride is prepared as the base substrate,
the production method further comprising: (g) after (f), polishing a surface of the base substrate remaining, wherein
a cycle including (b) to (g) is repeated.

### Supplementary Description 16

A peeled intermediate obtained by the production method for a nitride crystal substrate according to any one of the supplementary descriptions 11 to 15, comprising:
at least the cover layer and the regrowth layer.

### REFERENCE SIGNS LIST

10 Seed substrate for a nitride crystal growth
20 Peeled intermediate
50 Substrate
100 Base substrate
120 Main surface
200 Base layer
300 Intermediate layer
360 Void
400 Cover layer
500 Regrowth layer
510 C-Plane
810 Electrolyte
820 Process tank
840 Power source
842 Anode
844 Cathode
860 Current meter

What is claimed is:

1. A seed substrate for nitride crystal growth, comprising:
a base substrate;
an intermediate layer provided above the base substrate and including n-type group III nitride crystal; and
a cover layer provided on the intermediate layer and including group III nitride crystal having a carrier concentration lower than a carrier concentration of the intermediate layer, wherein
the intermediate layer is porous,
a surface of the cover layer has an arithmetic mean roughness of 1.0 nm or less, and
the surface of the cover layer has a root mean square roughness of 2.0 nm or less,
the arithmetic mean roughness and the root mean square roughness being values obtained when the surface of the cover layer is observed with an atomic force microscope in a field of view of 5 μm square.

2. The seed substrate for nitride crystal growth according to claim 1, wherein the intermediate layer has a thickness of more than 100 nm.

3. The seed substrate for nitride crystal growth according to claim 1, wherein
the intermediate layer includes a plurality of voids, and
a length of each of the plurality of voids in the intermediate layer in a direction along a main surface of the base substrate is 30 nm or more, when viewed in any cross section orthogonal to a main surface of the base substrate.

4. The seed substrate for nitride crystal growth according to claim 1, wherein
the intermediate layer includes a plurality of voids, and
a length of each of the plurality of voids in the intermediate layer in a direction along a main surface of the base substrate is 30 nm or more, when viewed in the cross section along the main surface of the base substrate and at a depth of 30 nm below a bottom surface of the cover layer.

5. The seed substrate for nitride crystal growth according to claim 1, wherein
the intermediate layer includes a plurality of voids, and
a depth of each of the plurality of voids in a thickness direction of the intermediate layer is more than 100 nm.

6. The seed substrate for nitride crystal growth according to claim 1, wherein the cover layer has a thickness of 10 nm or more and 2 μm or less.

7. The seed substrate for nitride crystal growth according to claim 1, wherein the base substrate has a diameter of 2 inches or more.

8. The seed substrate for nitride crystal growth according to claim 1, further comprising:
a base layer provided between the base substrate and the intermediate layer and including group III nitride crystal having a carrier concentration lower than a carrier concentration of the intermediate layer.

9. A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary.

10. The production method for a nitride crystal substrate according to claim 9, wherein in (f), the regrowth layer is peeled off spontaneously from the base substrate while decreasing a temperature after (e).

11. The production method for a nitride crystal substrate according to claim 9, wherein in (e), the regrowth layer is grown with (0001) as a growth surface.

12. The production method for a nitride crystal substrate according to claim 11, wherein in (f), the (0001) is warped into a spherical shape with an upper side thereof recessed by tensile stress in a direction along a main surface of the base substrate, generated in the regrowth layer, thereby spontaneously peeling off the regrowth layer from an outer periphery of the base substrate toward a center thereof.

13. The production method for a nitride crystal substrate according to claim 9, wherein in (a), a free-standing substrate comprising a group III nitride is prepared as the base substrate,
the production method further comprising: (g) after (f), polishing a surface of the base substrate remaining, wherein
a cycle including (b) to (g) is repeated.

14. A peeled intermediate obtained by the production method for a nitride crystal substrate according to claim 9, comprising:
at least the cover layer and the regrowth layer.
